(19) United States
(12) Patent Application Publication
(10) Pub. No.: US 2025/0089159 A1
(43) Pub. Date: Mar. 13, 2025

(54) STRETCHABLE DEVICE

(71) Applicant: Murata Manufacturing Co., Ltd., Nagaokakyo-shi (JP)

(72) Inventors: Koji YOSHIDA, Smyrna, GA (US); Hayato KATSU, Nagaokakyo-shi (JP); Toshifumi ASUKAI, Nagaokakyo-Shi (JP)

(21) Appl. No.: 18/955,236

(22) Filed: Nov. 21, 2024

Related U.S. Application Data
(63) Continuation of application No. PCT/JP2023/018134, filed on May 15, 2023.

(30) Foreign Application Priority Data
May 26, 2022 (JP) 2022-086226

(51) Int. Cl. H05K 1/02

(52) U.S. Cl. CPC H05K 1/0283; H05K 1/028; H05K 2201/0311; H05K 2201/0391; H05K 2201/10909

(57) ABSTRACT

A stretchable device including: a stretchable substrate; and a first electrode, a second electrode, and a third electrode on the stretchable substrate. A first ionization tendency of a conductive material as a main component of the third electrode is smaller than a second ionization tendency of a conductive material as a main component of the first electrode and a third ionization tendency of a conductive material as a main component of the second electrode, and a shortest distance between the first electrode and the third electrode is smaller than a shortest distance between the first electrode and the second electrode.

### CROSS REFERENCE TO RELATED APPLICATIONS

The present application is a continuation of International application No. PCT/JP2023/018134, filed May 15, 2023, which claims priority to Japanese Patent Application No. 2022-086226, filed May 26, 2022, the entire contents of each of which are incorporated herein by reference.

### TECHNICAL FIELD

The present disclosure relates to a stretchable device.

### BACKGROUND ART

Conventionally, as a stretchable device, there is one described in Japanese Patent No. 3518023 (Patent Document 1). This stretchable device includes a silver resin-based pattern provided on an insulating synthetic resin substrate, insulating resin provided on the silver resin-based pattern so as to expose a part of the silver resin-based pattern, and a fluorine-based resin thin film provided on an exposed portion of the silver resin-based pattern.
Patent Document 1: Japanese Patent No. 3518023

### SUMMARY OF THE DISCLOSURE

However, in the conventional stretchable device, there has been a possibility that migration occurs in the silver resin-based pattern. In particular, in a case where high load voltage is applied to the silver resin-based pattern, there has been a possibility that migration occurs significantly.

In view of the above, the present disclosure is to provide a stretchable device capable of suppressing migration.

In order to achieve the above object, a stretchable device according to an aspect of the present disclosure includes: a stretchable substrate; and a first electrode, a second electrode, and a third electrode on the stretchable substrate, in which a first ionization tendency of a conductive material as a main component of the third electrode is smaller than a second ionization tendency of a conductive material as a main component of the first electrode and a third ionization tendency of a conductive material as a main component of the second electrode, and a shortest distance between the first electrode and the third electrode is smaller than a shortest distance between the first electrode and the second electrode.

According to the stretchable device according to one aspect of the present disclosure, migration can be suppressed.

### BRIEF EXPLANATION OF THE DRAWINGS

FIG. 1 is a schematic perspective view illustrating a part of a stretchable device according to a first embodiment of the present disclosure.

FIG. 2 is a sectional view taken along II-II of FIG. 1.

FIG. 3A is an explanatory view for explaining a manufacturing method of the stretchable device.

FIG. 3B is an explanatory view for explaining a manufacturing method of the stretchable device.

FIG. 3C is an explanatory view for explaining a manufacturing method of the stretchable device.

FIG. 4A is a schematic sectional view illustrating the stretchable device according to a second embodiment of the present disclosure.

FIG. 4B is a schematic sectional view illustrating the stretchable device according to a variation of the second embodiment of the present disclosure.

FIG. 5 is a schematic sectional view illustrating the stretchable device according to a third embodiment of the present disclosure.

FIG. 6 is a schematic sectional view illustrating the stretchable device according to a fourth embodiment of the present disclosure.

FIG. 7 is a schematic sectional view illustrating the stretchable device according to a fifth embodiment of the present disclosure.

FIG. 8 is a schematic sectional view illustrating the stretchable device according to a sixth embodiment of the present disclosure.

FIG. 9 is a schematic sectional view illustrating the stretchable device according to a seventh embodiment of the present disclosure.

FIG. 10 is a schematic sectional view illustrating the stretchable device according to an eighth embodiment of the present disclosure.

FIG. 11A is a schematic sectional view illustrating the stretchable device according to a ninth embodiment of the present disclosure.

FIG. 11B is a schematic sectional view illustrating the stretchable device according to a variation of the ninth embodiment of the present disclosure.

FIG. 11C is a schematic sectional view illustrating the stretchable device according to a variation of the ninth embodiment of the present disclosure.

### DESCRIPTION OF THE PREFERRED EMBODIMENTS

Hereinafter, embodiments of the present disclosure will be described in detail with reference to the drawings. In each embodiment, a difference from description before the embodiment will be mainly described. Particularly, similar functions and effects achieved by similar configurations will not be mentioned sequentially for each embodiment. Among constituent elements in an embodiment below, a constituent element not described in an independent claim is described as an optional constituent element. Further, sizes and ratios of sizes of constituent elements illustrated in the drawings are not necessarily strict. Further, in the drawings, substantially the same configurations are denoted by the same reference numerals, and redundant description may be omitted or simplified.

The present disclosure is particularly effective for a circuit board in which an electrode is formed of metal which easily causes migration (movement of metal ions) such as silver or copper on a substrate which easily absorbs moisture, such as a stretchable substrate. The migration may proceed from a positive electrode to a negative electrode.

In a case where a substrate using silver, copper, or the like as an electrode is used in a humid environment, a function may be impaired by migration (for example, short circuit between electrodes). In order to prevent this, conventionally, a method of covering an electrode with a protective layer to improve migration resistance is used. However, in recent years, there has been a case where migration cannot be suppressed by the conventional technique for reasons such as miniaturization between electrodes due to miniaturization of a circuit board, increase in design voltage due to application diversification, and a change to substrate specifications inferior in migration resistance due to product characteristics. Further, in a medical device, a material used as a protective layer is also limited from the viewpoint of biocompatibility. For this reason, how to secure migration resistance is a problem. The present disclosure solves this problem.

### First Embodiment

(Schematic Configuration of Stretchable device 1)

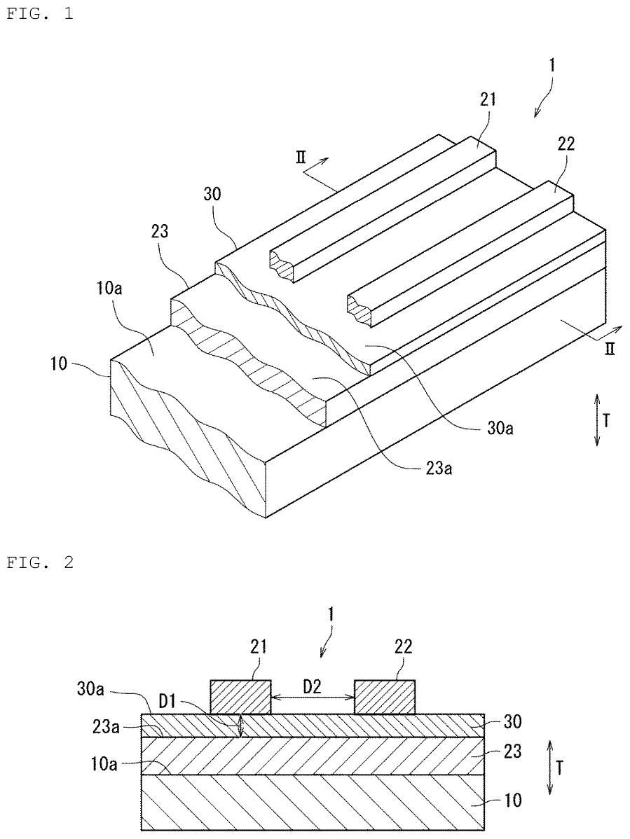

A schematic configuration of a stretchable device 1 according to a first embodiment will be described with reference to FIGS. 1 and 2. FIG. 1 is a schematic perspective view illustrating a part of the stretchable device 1. FIG. 2 is a sectional view taken along II-II of FIG. 1. Note that in the drawings of the present description, a thickness direction of a stretchable substrate is indicated by a double-headed arrow T.

The stretchable device 1 includes a stretchable substrate 10, and a first electrode 21, a second electrode 22, and a third electrode 23 provided on the stretchable substrate 10. The stretchable device 1 is, for example, attached to a living body and used to measure a biological signal.

Here, “on the stretchable substrate” refers to not an absolute direction such as a vertical upward direction defined in the direction of gravity but a direction toward the outside between the outside and the inside of the stretchable substrate with a surface of the stretchable substrate as a boundary. Therefore, the “on the stretchable substrate” is a relative direction determined by an orientation of a surface of the stretchable substrate. Further, “on” a certain element includes not only a position immediately above and in contact with the element (on) but also an upper position away from the element, that is, an upper position with another object on the element interposed between them or an upper position with a space between them (above).

The stretchable substrate 10 is a sheet-like or film-like substrate made from a stretchable resin material. Examples of the resin material include thermoplastic polyurethane (TPU). Thickness of the stretchable substrate 10 is not particularly limited, but is preferably 1 mm or less, more preferably 100 μm or less, still more preferably 50 μm or less from the viewpoint of preventing stretching of a surface of a living body from being impaired when the stretchable substrate 10 is attached to the living body. Further, thickness of the stretchable substrate 10 is preferably 1 μm or more. A shape of the stretchable substrate 10 is not particularly limited. In this embodiment, the stretchable substrate 10 has a shape extending in one direction as viewed in a thickness direction T.

The first electrode 21 and the second electrode 22 are electrodes for a signal. The first electrode 21 and the second electrode 22 may be wirings. Shapes of the first electrode 21 and the second electrode 22 are not particularly limited. In this embodiment, each electrode of the first electrode 21 and the second electrode 22 is a wiring and has a shape extending in one direction. A plurality of electrodes of the first electrode 21 and the second electrode 22 may be provided. Further, the first electrode and the second electrode do not need to be provided on the same plane.

The first electrode 21 and the second electrode 22 are formed of a conductive material. The first electrode 21 and the second electrode 22 preferably have stretchability. As the conductive material of the first electrode 21 and the second electrode 22, for example, metal foil of silver, copper, nickel or the like may be used, or a mixture of metal powder of silver, copper, nickel or the like and elastomeric resin such as epoxy resin, urethane resin, acrylic resin, or a silicone resin may be used. When conductivity of the material is emphasized, the conductive material of the first electrode 21 and the second electrode 22 is preferably silver. In this manner, the first electrode 21 and the second electrode 22 having low resistance can be formed.

The third electrode 23 is an electrode for suppressing migration. The third electrode 23 may be a wiring. Voltage for suppressing migration is applied to the third electrode 23. The third electrode 23 may be used for a signal in addition to migration suppression. A shape of the third electrode 23 is not particularly limited. In this embodiment, the third electrode 23 has a plate shape. The third electrode 23 may be a dummy electrode that does not transmit or receive a signal.

The third electrode 23 is formed of a conductive material. The third electrode 23 preferably has stretchability. As the conductive material of the third electrode 23, for example, a material having migration resistance (in other words, ionization tendency is small) such as carbon or platinum is used.

The ionization tendency of a conductive material as a main component of the third electrode 23 is smaller than ionization tendency of a conductive material as a main component of the first electrode 21 and ionization tendency of a conductive material as a main component of the second electrode 22. The “conductive material as a main component” refers to a component of an element having a largest abundance ratio (% by weight) among elements showing conductivity contained in an electrode. For example, both the first electrode 21 and the second electrode 22 can be silver electrodes, and the third electrode 23 can be a carbon electrode. Ionization tendency of a conductive material as a main component of the third electrode 23, that is, carbon is smaller than ionization tendency of a conductive material as a main component of the first electrode 21, that is, silver, and ionization tendency of a conductive material as a main component of the second electrode 22, that is, silver.

As illustrated in FIG. 2, a shortest distance D1 between the first electrode 21 and the third electrode 23 is smaller than a shortest distance D2 between the first electrode 21 and the second electrode 22. The shortest distance D1 refers to a minimum value of a distance of a facing direction of the first electrode 21 and the third electrode 23 (in this embodiment, the thickness direction T of the stretchable substrate 10). The shortest distance D2 refers to a minimum value of a distance of a facing direction of the first electrode 21 and the second electrode 22 (in this embodiment, a left-right direction in FIG. 2). The shortest distance D1 and the shortest distance D2 only need to be measured in a section parallel to the thickness direction T of the stretchable substrate 10 and intersecting the first electrode 21, the second electrode 22, and the third electrode 23. In this embodiment, the shortest distance D1 and the shortest distance D2 may also be measured, for example, in a section passing through the center in an extending direction of the first electrode 21 and orthogonal to the extending direction of the first electrode 21.

According to the above configuration, since the shortest distance D1 between the first electrode 21 and the third electrode 23 is smaller than the shortest distance D2 between the first electrode 21 and the second electrode 22, intensity of an electric field formed between the first electrode 21 and the third electrode 23 is larger than intensity of an electric field formed between the first electrode 21 and the second electrode 22. For this reason, pulling force between the first electrode 21 and the third electrode 23 is larger than pulling force between the first electrode 21 and the second electrode 22. As a result, migration that may occur between the first electrode 21 and the second electrode 22 can be suppressed. Further, since ionization tendency of a conductive material as a main component of the third electrode 23 is smaller than ionization tendency of a conductive material as a main component of the first electrode 21 and ionization tendency of a conductive material as a main component of the second electrode 22, migration that may occur between the first electrode 21 and the third electrode 23 is suppressed when pulling force between the first electrode 21 and the third electrode 23 becomes larger than pulling force between the first electrode 21 and the second electrode 22. In this manner, it is possible to suppress migration that may occur in the stretchable device 1.

(Detailed Configuration of Stretchable Device 1) Next, a detailed configuration of the stretchable device 1 will be described.

As illustrated in FIGS. 1 and 2, the stretchable substrate 10 has a first main surface 10a. The first electrode 21, the second electrode 22, and the third electrode 23 are provided on the first main surface 10a. The first electrode 21 and the second electrode 22 are arranged on the same plane. The third electrode 23 is arranged at a position different from the first electrode 21 and the second electrode 22 in the thickness direction T of the stretchable substrate 10. The stretchable device 1 includes an insulating layer 30 provided at least between the first electrode 21 and the third electrode 23 and between the second electrode 22 and the third electrode 23.

Here, “on the first main surface” refers to not an absolute direction such as a vertical upward direction defined in the direction of gravity but a direction toward the outside between the outside and the inside of the stretchable substrate with the first main surface of the stretchable substrate as a boundary. Therefore, the “on the first main surface” is a relative direction determined by an orientation of the first main surface of the stretchable substrate.

According to the above configuration, contact between the first electrode 21 and the second electrode 22, and the third electrode 23 can be prevented by the insulating layer 30. That is, a distance between the first electrode 21 and the third electrode 23 can be made sufficiently small as compared with a case where the first electrode 21, the second electrode 22, and the third electrode 23 are arranged on the same plane. For this reason, it is possible to further suppress migration that may occur in the stretchable device 1. On the other hand, in a case where the first electrode 21, the second electrode 22, and the third electrode 23 are arranged on the same plane, it is difficult to make a distance between the first electrode 21 and the third electrode 23 sufficiently small in consideration of print blur at the time of electrode formation. Further, the insulating layer 30 can suppress a short circuit between the first electrode 21 and the third electrode 23 and between the second electrode 22 and the third electrode 23.

The third electrode 23, the insulating layer 30, the first electrode 21, and the second electrode 22 are laminated in this order from the first main surface 10a side of the stretchable substrate 10. According to this configuration, since the insulating layer 30 and the third electrode 23 exist between the first electrode 21 and the second electrode 22, and the stretchable substrate 10, it is possible to prevent moisture from entering the first electrode 21 and the second electrode 22 from the stretchable substrate 10 side and further suppress migration that may occur between the first electrode 21 and the second electrode 22.

Specifically, the third electrode 23 is provided on the entire first main surface 10a of the stretchable substrate 10. In other words, the third electrode 23 is provided in a plate shape so as to cover the entire first main surface 10a of the stretchable substrate 10. The insulating layer 30 is provided on an entire surface 23a located on the side opposite to the stretchable substrate 10 side of the third electrode 23. In the present embodiment, the surface 23a of the third electrode 23 corresponds to a surface located on the opposite side of a surface of the third electrode facing the stretchable substrate 10. The insulating layer 30 is provided in a plate shape so as to cover the entire surface 23a of the third electrode 23. The first electrode 21 and the second electrode 22 are provided on a part of a surface 30a on the side opposite to the third electrode 23 side of the insulating layer 30. The first electrode 21 extends along an extending direction of the stretchable substrate 10. The second electrode 22 extends along an extending direction of the stretchable substrate 10. The first electrode 21 and the second electrode 22 are separated from each other by the shortest distance D2.

The insulating layer 30 electrically insulates the first electrode 21 and the second electrode 22, and the third electrode 23. The insulating layer 30 preferably has stretchability. The insulating layer 30 may or may not have water absorbency. A shape of the insulating layer 30 is not particularly limited as long as the first electrode 21 and the second electrode 22, and the third electrode 23 can be electrically insulated. An insulating material of the insulating layer 30 is not particularly limited as long as the first electrode 21 and the second electrode 22, and the third electrode 23 can be electrically insulated. An insulating material of the insulating layer 30 is, for example, polyester resin or the like.

### (Other Preferable Configurations)

Preferably, polarity of potential of the first electrode 21 is different from polarity of potential of the second electrode 22, and polarity of potential of the third electrode 23 is different from polarity of potential of the first electrode 21. According to this configuration, signals having different polarities can be extracted from the first electrode 21 and the second electrode 22. In a case where a plurality of electrodes of the first electrode 21 and the second electrode 22 exist, the first electrode 21 and the second electrode 22 may be alternately arranged along a direction orthogonal to an extending direction of the first electrode 21, polarity of potential of the first electrode 21 may be made different from polarity of potential of the second electrode 22, and polarity of potential of the third electrode 23 may be made different from polarity of potential of the first electrode 21. By the above, a plurality of signals having different polarities can be extracted from the first electrode 21 and the second electrode 22.

Preferably, polarity of potential of the first electrode 21 is negative. In this case, polarity of potential of the second electrode 22 is positive, and polarity of potential of the third electrode 23 is positive. As described above, since the shortest distance D1 between the first electrode 21 and the third electrode 23 is smaller than the shortest distance D2 between the first electrode 21 and the second electrode 22, intensity of an electric field formed between the first electrode 21 and the third electrode 23 is larger than intensity of an electric field formed between the first electrode 21 and the second electrode 22. For this reason, according to the above configuration, movement of a cation from the second electrode 22 to the first electrode 21 via the insulating layer 30 can be suppressed, and migration that may occur between the first electrode 21 and the second electrode 22 can be suppressed. Further, since polarity of potential of the third electrode is positive, movement of a cation from the second electrode 22 to the third electrode 23 via the insulating layer 30 is suppressed. Further, as described above, since ionization tendency of a conductive material as a main component of the third electrode 23 is smaller than ionization tendency of a conductive material as a main component of the first electrode 21 and ionization tendency of a conductive material as a main component of the second electrode 22, movement of a cation from the third electrode 23 to the first electrode 21 via the insulating layer 30 is suppressed. As described above, according to the above configuration, migration that may occur in the stretchable device 1 can be further suppressed.

On the other hand, in a case where the third electrode 23 is not provided, when polarity of potential of the first electrode 21 is negative and polarity of potential of the second electrode 22 is positive, a cation may easily move from the second electrode 22 to the first electrode 21 via the insulating layer 30. As a result, migration may occur between the first electrode 21 and the second electrode 22. Further, also in a case where the third electrode 23 is provided, in a case where ionization tendency of a conductive material as a main component of the third electrode 23 is the same as or larger than ionization tendency of a conductive material as a main component of the first electrode 21 and ionization tendency of a conductive material as a main component of the second electrode 22, a cation may easily move from the third electrode 23 to the first electrode 21 via the insulating layer 30. As a result, migration may occur between the first electrode 21 and the third electrode 23.

Preferably, the third electrode 23 overlaps the entire first electrode 21 as viewed from the thickness direction T of the stretchable substrate 10. More preferably, the third electrode 23 overlaps the entire first electrode 21 when viewed from the thickness direction T of the stretchable substrate 10, and a plane area of the third electrode 23 is larger than a plane area of the first electrode 21. According to this configuration, since the third electrode can be easily aligned, the third electrode 23 can be easily formed. Further, since the first electrode 21 is arranged immediately above the third electrode 23, the shortest distance D1 between the first electrode 21 and the third electrode 23 can be made further smaller, and migration that may occur between the first electrode 21 and the second electrode 22 can be further suppressed.

Preferably, the third electrode 23 overlaps the entire first electrode 21 and the entire second electrode 22 as viewed from the thickness direction T of the stretchable substrate 10. More preferably, the third electrode 23 overlaps the entire first electrode 21 and the entire second electrode 22 as viewed from the thickness direction T of the stretchable substrate 10 and the third electrode 23 overlapping the entire first electrode 21 and the third electrode overlapping the entire second electrode 22 are integrated, and a plane area of the third electrode 23 is larger than a plane area obtained by combining a plane area of the first electrode 21 and a plane area of the second electrode 22. According to this configuration, for example, the third electrode 23 can be formed in a plate shape so as to cover the entire first main surface 10a of the stretchable substrate 10, and patterning of the third electrode 23 becomes unnecessary, so that the third electrode 23 can be easily formed. Further, since the first electrode 21 is arranged immediately above the third electrode 23, the shortest distance D1 between the first electrode 21 and the third electrode 23 can be made further smaller, and migration that may occur between the first electrode 21 and the second electrode 22 can be further suppressed.

Preferably, a protective layer (not illustrated) is provided on the insulating layer 30 so as to cover the first electrode 21 and the second electrode 22. The protective layer is preferably a stretchable resin material, for example, ionomer resin, polyester resin, styrene resin, olefin resin, epoxy resin, urethane resin, acrylic resin, or silicone resin. According to this configuration, the first electrode 21 and the second electrode 22 can be protected from an external environment. Further, the insulating layer 30 may be arranged so as to cover the first electrode 21 and the second electrode 22.

### (Method of Manufacturing Stretchable Device 1)

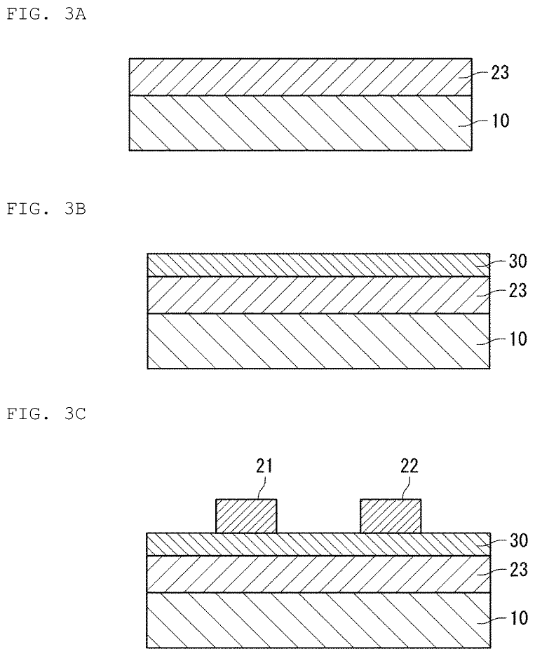

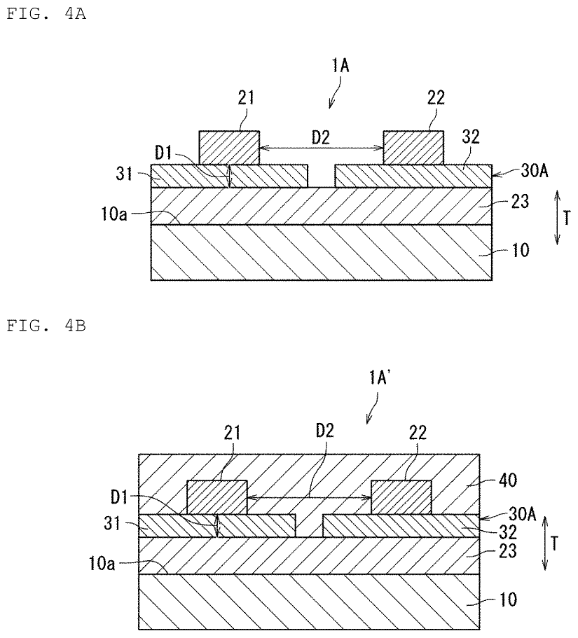

Next, a method of manufacturing the stretchable device 1 will be described with reference to FIGS. 3A, 3B, and 3C. FIGS. 3A, 3B, and 3C are explanatory views for explaining a method of manufacturing the stretchable device 1. Note that, in description below, a process condition, a material to be used, and the like of the stretchable device 1 are specifically described, but description below is merely an example of a method of manufacturing the stretchable device 1, and the method of manufacturing the stretchable device 1 is not limited by the process condition and material to be used below.

As illustrated in FIG. 3A, the third electrode 23 is formed on the stretchable substrate 10 by, for example, screen printing. The stretchable substrate 10 is, for example, thermoplastic polyurethane (TPU). A process condition and a material to be used are, for example, as described below.
Third electrode material: carbon electrode 7105 manufactured by DuPont
Stretchable substrate: DUS605_6UVPT (50 μm thick) manufactured by Sheedom Co., Ltd.
Printing plate: SP plate (Mesh: #500, linear 18 μm, emulsion thickness 11 μm, internal dimension 280 mm square), pattern area: 150×150 mm
Printing condition: squeegee: micro squeegee (rubber hardness: 70°), squeegee pressure: 200 N/160 mm width, squeegee speed: 150 mm/s, squeegee attack angle: 60°, distance: 1.5 mm
Drying condition: convection oven 100° C.×30 minutes

As illustrated in FIG. 3B, the insulating layer 30 is formed on the third electrode 23 by, for example, screen printing. A process condition and a material to be used are, for example, as described below.
Insulating layer material: ELECTRODAG 452SS manufactured by Henkel Corporation
Printing plate: SP plate (Mesh: #352, linear 23 μm, emulsion thickness 17 μm, internal dimension 280 mm square), pattern area: 150×150 mm
Printing condition: squeegee: micro squeegee (rubber hardness: 70°), squeegee pressure: 200 N/160 mm width, squeegee speed: 150 mm/s, squeegee attack angle: 70°, distance: 1.5 mm
Curing condition: UV light irradiation; 500 mJ/cm² with i-line (365 nm)

As illustrated in FIG. 3C, the first electrode 21 and the second electrode 22 are formed on the insulating layer 30 by, for example, screen printing. A process condition and a material to be used are, for example, as described below.
Electrode material: Silver electrode 5064 manufactured by DuPont
Printing plate: SP plate (Mesh: #500, linear 18 μm, emulsion thickness 11 μm, internal dimension 280 mm square), pattern area: 150×150 mm
Printing condition: squeegee: micro squeegee (rubber hardness: 70°), squeegee pressure: 100 N/160 mm width, squeegee speed: 150 mm/s, squeegee attack angle: 50°, distance: 1.5 mm
Drying condition: convection oven 100° C.×30 minutes

### Second Embodiment

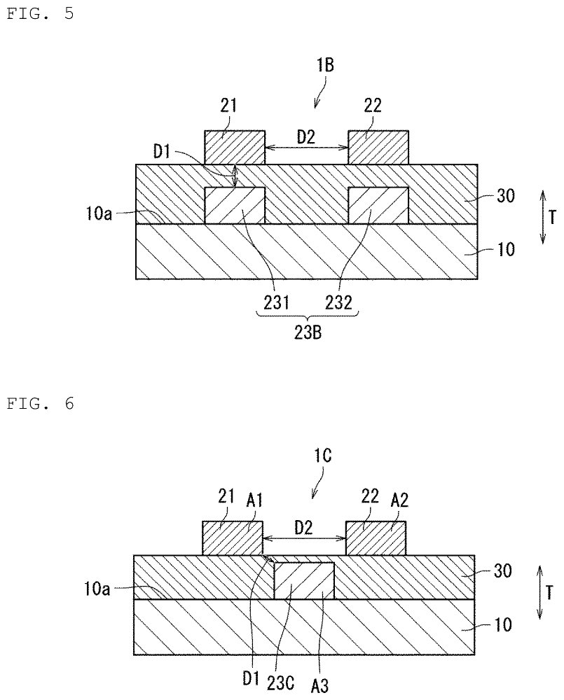

Hereinafter, a stretchable device 1A according to a second embodiment will be described with reference to FIG. 4A. FIG. 4A corresponds to a II-II section of FIG. 1. The stretchable device 1A is different from the stretchable device 1 according to the first embodiment in a shape of an insulating layer.

An insulating layer 30A of the stretchable device 1A includes a first portion 31 provided between the first electrode 21 and the third electrode 23, and a second portion 32 provided between the second electrode 22 and the third electrode 23. The first portion 31 and the second portion 32 are separated from each other. In short, the insulating layer 30A is divided into the first portion 31 and the second portion 32 unlike the insulating layer 30 of the first embodiment. The insulating layer 30A may be divided into three or more portions.

Specifically, the first portion 31 is provided between the first electrode 21 and the third electrode 23, and electrically insulates the first electrode 21 and the third electrode 23. The first portion 31 extends along an extending direction of the first electrode 21. The second portion 32 is provided between the second electrode 22 and the third electrode 23, and electrically insulates the second electrode 22 and the third electrode 23. The second portion 32 extends along an extending direction of the second electrode 22. The first portion 31 and the second portion 32 are separated from each other at a predetermined interval in a facing direction of the first electrode 21 and the second electrode 22 (left-right direction in FIG. 4A).

According to the above configuration, a path through which an ion moves in the insulating layer 30A can be cut off between the first electrode 21 and the second electrode 22. Therefore, migration that may occur between the first electrode 21 and the second electrode 22 can be further suppressed.

According to the above configuration, the insulating layer 30A is arranged at an interval on the stretchable substrate 10. By the above, a plane area of the insulating layer 30A is smaller than that in a case where the insulating layer is continuous, and thus, it is possible to further reduce influence of the insulating layer 30A on stretchability of the stretchable device 1A. For this reason, according to the above configuration, it is possible to obtain a stretchable device having more excellent stretchability while suppressing migration by an insulating layer.

Further, a stretchable device may be attached to a living body, for example. In such use for a living body, a stretchable device may be required to have air permeability in order to reduce discomfort such as stuffiness at the time the stretchable device is worn. This may be realized, for example, by using a material having air permeability as a material of the stretchable substrate 10 and the like. On the other hand, in order to suppress migration between electrodes, it is preferable to use a material having low air permeability as an insulating layer. For this reason, when an insulating layer is arranged over the entire stretchable device 1A as viewed in the thickness direction T of the stretchable substrate 10, there is a possibility that air permeability is reduced.

According to the above configuration, the first portion 31 and the second portion 32 of the insulating layer 30A are arranged to be separated from each other. For this reason, the stretchable device 1A includes a region where the insulating layer 30A is not provided between the first portion 31 and the second portion 32 on the stretchable substrate 10A. This makes it possible to suppress decrease in air permeability of the stretchable device due to the insulating layer. That is, a stretchable device having good air permeability is realized while migration is suppressed by the insulating layer.

Further, in the first embodiment, a continuous one of the insulating layer 30 is formed over the entire stretchable device as viewed from the thickness direction T of the stretchable substrate 10, whereas in the second embodiment, a plurality of insulating layers having a small plane area are provided. That is, in the stretchable device 1A of the second embodiment, the insulating layer 30A is divided into the first portion 31 and the second portion 32, so that an area of insulating layers provided continuously can be reduced. By the above film thickness of the insulating layer can be more precisely controlled as compared with a case where one continuous insulating layer is provided over a wide range. Specifically, nonuniformity of thickness of the insulating layer due to printing unevenness or the like is reduced, and the stretchable device 1A including the insulating layer 30A having a more uniform thickness may be provided.

As illustrated in FIG. 4A, thickness of the insulating layer 30A may correspond to the shortest distance D1 between the first electrode 21 and the third electrode 23. Since the insulating layer 30A has uniform thickness as described above, the shortest distance D1 is more uniform between the first electrode 21 and the third electrode 23, so that migration can be more suitably suppressed.

Note that, in a case where a protective layer 40 covering the first electrode 21 and the second electrode 22 is provided, the protective layer 40 may exist in the space between the first portion 31 and the second portion 32 (see FIG. 4B). This makes it possible to further suppress migration that may occur between the first electrode 21 and the second electrode 22. Further, since the protective layer 40 exists so as to bite into a space between the first portion 31 and the second portion 32, the protective layer may be suitably held by an anchor effect. By the above, peeling of the protective layer 40 from the stretchable device 1A can be suitably suppressed.

### Third Embodiment

Hereinafter, a stretchable device 1B according to a third embodiment will be described with reference to FIG. 5. FIG. 5 corresponds to a II-II section of FIG. 1. The stretchable device 1B is different from the stretchable device 1 according to the first embodiment in a shape of the third electrode.

A third electrode 23B of the stretchable device 1B has a shape corresponding to shapes of the first electrode 21 and the second electrode 22. Specifically, the third electrode 23B includes a first portion 231 having a shape corresponding to a shape of the first electrode 21 and a second portion 232 having a shape corresponding to a shape of the second electrode 22. That is, the first portion 231 extends linearly along an extending direction of the first electrode 21. The second portion 232 extends linearly along an extending direction of the second electrode 22. In short, the third electrode 23B is divided into the first portion 231 and the second portion 232 unlike the third electrode 23 of the first embodiment. The first portion 231 overlaps the first electrode 21 as viewed from the thickness direction T of the stretchable substrate 10. The second portion 232 overlaps the second electrode 22 as viewed from the thickness direction T of the stretchable substrate 10.

According to the above configuration, since the third electrode 23B is divided, an electric field formed between the first electrode 21 and the third electrode 23B can be concentrated as compared with a case where the third electrode 23B is not divided. Therefore, pulling force between the first electrode 21 and the third electrode 23B is further larger than pulling force between the first electrode 21 and the second electrode 22. As a result, migration that may occur between the first electrode 21 and the second electrode 22 can be further suppressed. Further, since a plane area of the third electrode 23B can be reduced as compared with a case where the third electrode 23B is not divided, stretchability of the stretchable device 1B can be improved.

In the stretchable device, a transparent or translucent material can be used as a material other than an electrode (that is, the stretchable substrate 10, the insulating layer 30, and/or the protective layer, and the like). According to the above configuration, the third electrode 23B is arranged in a region overlapping the first electrode 21 or the second electrode 22 as viewed from the thickness direction T of the stretchable substrate 10 without covering the first main surface 10a of the transparent or translucent stretchable substrate 10 over a front surface. That is, as viewed from the thickness direction T of the stretchable substrate 10, in the stretchable device, an electrode is arranged only in a partial region of the first main surface 10a of the transparent or translucent stretchable substrate 10. For this reason, the stretchable device can include a transparent or translucent region in a region not including an electrode as viewed from the thickness direction T of the stretchable substrate 10. In this manner, an attachment position of the stretchable device can be visually recognized through the transparent or translucent region.

Note that the second portion 232 of the third electrode 23B is preferably provided in order to alleviate unevenness of an upper surface of the insulating layer 30 that may be generated by the third electrode 23B, but does not need to be provided. In this case, since an electric field formed between the first electrode 21 and the third electrode 23B can be further concentrated, migration that may occur between the first electrode 21 and the second electrode 22 can be further suppressed.

### Fourth Embodiment

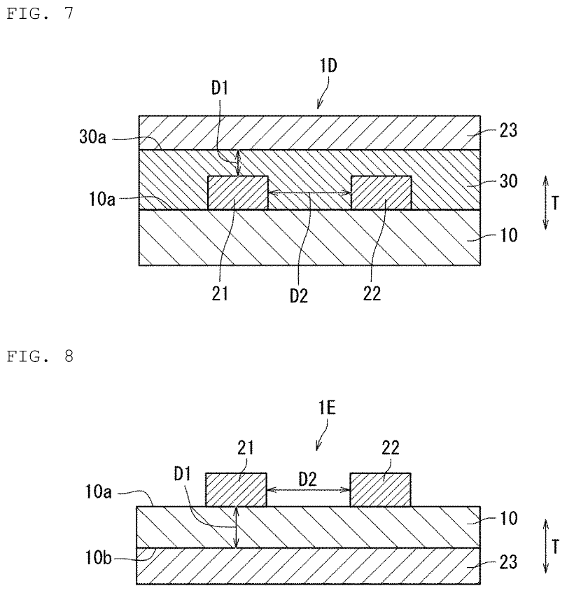

Hereinafter, a stretchable device 1C according to a fourth embodiment will be described with reference to FIG. 6. FIG. 6 corresponds to a II-II section of FIG. 1. The stretchable device 1C is different from the stretchable device 1 according to the first embodiment in a shape of the third electrode.

A third electrode 23C of the stretchable device 1C does not overlap the first electrode 21 or the second electrode 22 as viewed from the thickness direction T of the stretchable substrate 10. Specifically, the third electrode 23C is provided on a part of the first main surface 10a of the stretchable substrate 10. The third electrode 23C extends linearly along an extending direction of the first electrode 21. The third electrode 23C is arranged between the first electrode 21 and the second electrode 22 as viewed from the thickness direction T of the stretchable substrate 10.

According to the above configuration, in a section orthogonal to an extending direction of the first electrode 21, the first electrode 21, the third electrode 23, and the second electrode 22 can be alternately arranged in a staggered pattern along a direction orthogonal to the thickness direction T of the stretchable substrate, so that stretchability of the stretchable device 1C can be made uniform. In particular, as described above, in a case where the insulating layer 30 is arranged so as to cover the first electrode 21 and the second electrode 22, stretchability of the stretchable device 1C can be made more uniform.

Furthermore, according to the above configuration, thickness of the insulating layer 30 can be reduced. In the above configuration, as viewed from the thickness direction T of the stretchable substrate 10, the third electrode 23C is arranged in a staggered manner so as not to overlap the first electrode 21 or the second electrode 22. That is, since the third electrode 23C is offset with respect to the first electrode 21 and the second electrode 22, thickness of the insulating layer 30 can be reduced while the shortest distance D1 between the first electrode 21 and the third electrode 23C is suitably secured. Specifically, the insulating layer 30 covering the third electrode 23C only needs to have a small thickness as compared with a case where the first electrode 21, the second electrode 22, and the third electrode 23C overlap in the thickness direction T (for example, the configuration illustrated in FIG. 5). Accordingly, height of the stretchable device can be further reduced.

In a case where the insulating layer 30 has stretchability, thickness of the insulating layer 30 in a stretched state may be smaller than thickness of the insulating layer 30 in a non-stretched state in a sectional view illustrated in FIG. 6. According to the above configuration, since the third electrode 23C does not overlap the first electrode 21 or the second electrode 22 as viewed from the thickness direction T of the stretchable substrate 10, if the thickness of the insulating layer 30 is relatively reduced by stretching, contact between electrodes can be suitably prevented.

Preferably, in a section parallel to the thickness direction T of the stretchable substrate 10 and intersecting the first electrode 21 and the third electrode 23C, a sectional area A3 of the third electrode 23C is 105% or less of a sectional area A1 of the first electrode 21. According to this configuration, stretchability of the stretchable device 1C can be improved. More preferably, the sectional area A3 of the third electrode 23C is 100% or less of the sectional area A1 of the first electrode 21.

Similarly, preferably, in a section parallel to the thickness direction T of the stretchable substrate 10 and intersecting the second electrode 22 and the third electrode 23C, the sectional area A3 of the third electrode 23C is 105% or less of a sectional area A2 of the second electrode 22. More preferably, the sectional area A3 of the third electrode 23C is 100% or less of the sectional area A2 of the second electrode 22. As sectional areas of the first electrode 21, the second electrode 22, and the third electrode 23 are closer to each other, stretchability of the stretchable device 1C can be made more uniform.

Preferably, in a section parallel to the thickness direction T of the stretchable substrate 10 and intersecting the first electrode 21 and the third electrode 23C, a sectional area A3 of the third electrode 23C is 10% or more of the sectional area A1 of the first electrode 21. The sectional area A3 of the third electrode 23C is more preferably 50% or more, still more preferably 90% or more of the sectional area A1 of the first electrode 21. According to this configuration, sectional areas of the first electrode 21, the second electrode 22, and the third electrode 23 are closer to each other, and stretchability of the stretchable device 1C can further be made more uniform.

Similarly, preferably, in a section parallel to the thickness direction T of the stretchable substrate 10 and intersecting the second electrode 22 and the third electrode 23C, the sectional area A3 of the third electrode 23C is 10% or more of the sectional area A2 of the second electrode 22. The sectional area A3 of the third electrode 23C is more preferably 50% or more, still more preferably 90% or more of the sectional area A2 of the second electrode 22. In a case where the sectional area A3 of the third electrode 23C is too small, an effect of suppressing migration can be reduced. By setting a lower limit of the sectional area A3 of the third electrode 23C as described above, migration that may occur between the first electrode 21 and the second electrode 22 can be effectively suppressed.

### Fifth Embodiment

Hereinafter, a stretchable device 1D according to a fifth embodiment will be described with reference to FIG. 7. FIG. 7 corresponds to a II-II section of FIG. 1. The stretchable device 1D is different from the stretchable device 1 according to the first embodiment in a positional relationship between the first electrode and the second electrode, the insulating layer, and the third electrode.

The first electrode 21 and the second electrode 22 are provided on the first main surface 10a of the stretchable substrate 10. The insulating layer 30 is provided on the first main surface 10a of the stretchable substrate 10 so as to cover the first electrode 21 and the second electrode 22.

The third electrode 23 is provided on the surface 30a of the insulating layer 30 on the side opposite to the first main surface 10a side of the stretchable substrate 10. Note that, in this embodiment, a position where the third electrode 23 is provided is not particularly limited, and for example, the third electrode 23 may be provided below the first electrode 21 and the second electrode 22.

According to the above configuration, since the first electrode 21 and the second electrode 22 are covered with the insulating layer 30, the first electrode 21 and the second electrode 22 can be protected from moisture that may enter from the upper side (the upper side in FIG. 7) of the stretchable substrate 10. Further, in a case where the third electrode 23 is provided on the surface 30a of the insulating layer 30, patterns of the first electrode 21 and the second electrode 22 can be hidden by the third electrode 23. In such a configuration, the third electrode 23 can also serve as a protective layer for the first electrode 21 and the second electrode 22. For example, the third electrode 23 can serve as a protective layer that prevent moisture from entering the inside of the stretchable device 1D from the third electrode 23 side (upper side in FIG. 7).

### Sixth Embodiment

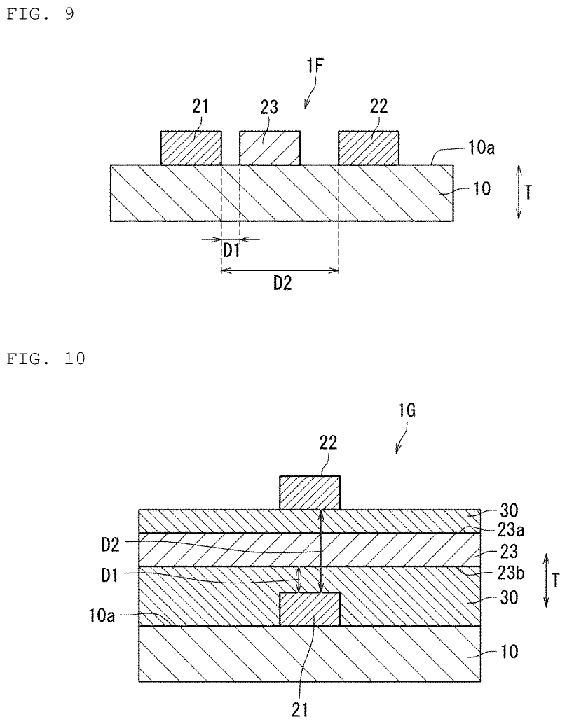

Hereinafter, a stretchable device 1E according to a sixth embodiment will be described with reference to FIG. 8. FIG. 8 corresponds to a II-II section of FIG. 1. The stretchable device 1E is different from the stretchable device 1 according to the first embodiment in that the insulating layer is not provided and a position where the third electrode is provided.

The stretchable substrate 10 has the first main surface 10a and a second main surface 10b facing each other, the first electrode 21 and the second electrode 22 are provided on the first main surface 10a, and the third electrode 23 is provided on the second main surface 10b. In this embodiment, since electrical insulation between the first electrode 21 and the second electrode 22, and the third electrode 23 can be secured by the stretchable substrate 10, the insulating layer 30 is not provided.

According to the above configuration, since it is not necessary to provide the insulating layer 30, a manufacturing process can be simplified, and manufacturing cost can be reduced. Further, with a configuration not provided with the insulating layer 30, thickness of the stretchable device 1E is reduced as a whole, and height of the stretchable device can be further reduced.

Furthermore, in the above configuration, the shortest distance D1 between the first electrode 21 and the third electrode 23 corresponds to thickness of the stretchable substrate 10. For this reason, by providing the first electrode 21 and the second electrode 22 on the one main surface 10a of the stretchable substrate 10 and providing the third electrode 23 on the other main surface 10b, the first electrode 21 and the third electrode 23 can be uniformly separated by the same dimension as thickness of the stretchable substrate 10.

In the above configuration, the third electrode 23 may be a gel electrode. By using a gel electrode as the third electrode 23, the stretchable device can be easily attached to a living body or the like. That is, by using a gel electrode as the third electrode 23, the third electrode 23 can function as an adhesive layer for causing the stretchable device to adhere to a living body or the like. The gel electrode includes, for example, a conductive gel material containing water, alcohol, a humectant, an electrolyte, and the like. Examples of such a gel material include hydrogel having adhesiveness.

### Seventh Embodiment

Hereinafter, a stretchable device 1F according to a seventh embodiment will be described with reference to FIG. 9. FIG. 9 corresponds to a II-II section of FIG. 1. The stretchable device 1F is different from the stretchable device 1 according to the first embodiment in that the insulating layer is not provided and a position where the third electrode is provided.

The first electrode 21, the second electrode 22, and the third electrode 23 are provided on the same plane. Specifically, similarly to the first electrode 21 and the second electrode 22, the third electrode 23 is provided on the first main surface 10a of the stretchable substrate 10. The third electrode 23 extends linearly along an extending direction of the first electrode 21. The third electrode 23 is arranged between the first electrode 21 and the second electrode 22. The third electrode 23 is separated from each of the first electrode 21 and the second electrode 22. In this embodiment, since the first electrode 21, the second electrode 22, and the third electrode 23 are provided on the same plane, the insulating layer 30 is not provided.

According to the above configuration, since it is not necessary to provide the insulating layer 30, a manufacturing process can be simplified, and manufacturing cost can be reduced. Further, since it is not necessary to provide the insulating layer 30, the stretchable device 1F can be made thin.

Furthermore, as the third electrode 23 is arranged between the first electrode 21 and the second electrode 22, the third electrode 23 can suitably prevent blur of the second electrode 22 at the time of printing from reaching the first electrode 21. That is, the third electrode 23 may also contribute to suppression of printing blur of the second electrode 22. For this reason, according to the above configuration, the distance D2 between the first electrode 21 and the second electrode 22 can be further reduced, and the stretchable device can be further downsized.

Further, according to the above configuration, since it is possible to arrange the first electrode 21, the second electrode 22, and the third electrode 23 by controlling a print pattern on the first main surface 10a, the distance D1 between the first electrode 21 and the third electrode 23 and the distance D2 between the first electrode 21 and the second electrode 22 can be more easily controlled.

### Eighth Embodiment

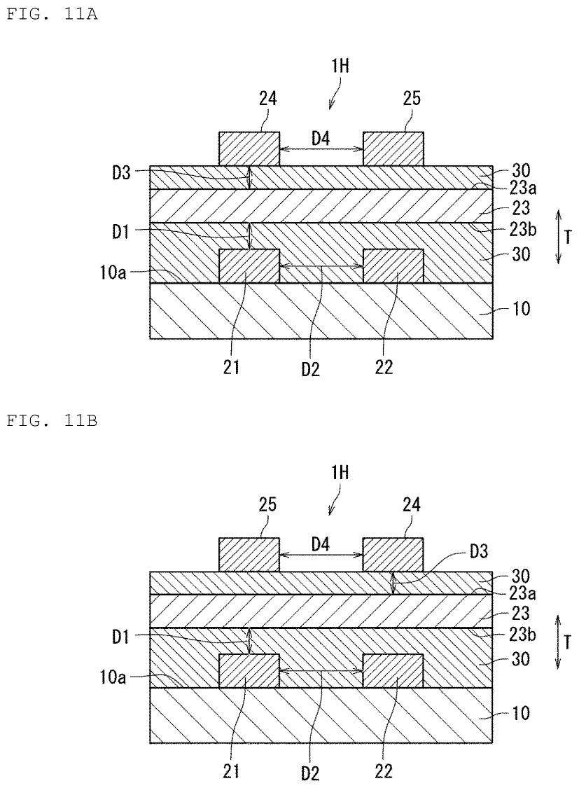

Hereinafter, a stretchable device 1G according to an eighth embodiment will be described with reference to FIG. 10. FIG. 10 corresponds to a II-II section of FIG. 1. The stretchable device 1G is different from the stretchable device 1 according to the first embodiment in that the first electrode 21 and the second electrode 22 are laminated so as to sandwich the third electrode 23 and the insulating layer 30.

As illustrated in FIG. 10, the first electrode 21 and the second electrode 22 are laminated by sandwiching the third electrode 23. Specifically, the first electrode 21 is provided on the first main surface 10a of the stretchable substrate 10. The insulating layer 30 is provided on the first main surface 10a of the stretchable substrate 10 so as to cover the first electrode 21. The third electrode 23 is provided so as to face the first electrode 21 with the insulating layer 30 interposed between them on a surface 23b (hereinafter, also referred to as a second surface 23b) side facing the first main surface 10a of the stretchable substrate 10. The insulating layer 30 is further provided on a surface 23a (hereinafter, also referred to as a first surface 23a) of the third electrode 23 located on the opposite side of the second surface 23b. The second electrode 22 is arranged on the insulating layer 30 located on the first surface 23a. The insulating layer is provided between the first electrode 21 and the third electrode 23 and between the second electrode 22 and the third electrode 23. That is, the third electrode 23 includes the insulating layer 30 on both surfaces of the second surface 23b facing the first main surface of the stretchable substrate 10 and the first surface 23a on the opposite side of the second surface 23b. In other words, the third electrode 23 is located between two of the insulating layers 30. By the above, the stretchable device 1G has a structure in which the first electrode 21, the insulating layer 30, the third electrode 23, the insulating layer 30, and the second electrode 22 are laminated in this order on the stretchable substrate 10.

Note that arrangement of the first electrode 21 and the second electrode 22 may be reversed. That is, the second electrode 22 may be located between the stretchable substrate 10 and the third electrode 23, and the first electrode 22 may be located on the first surface 23a side of the third electrode.

According to the above configuration, since the first electrode 21 and the second electrode 22 are physically separated by the third electrode 23, migration between the first electrode 21 and the second electrode 22 can be more suitably prevented. Furthermore, as described above, since ionization tendency of a conductive material as a main component of the third electrode 23 is smaller than ionization tendency of a conductive material as a main component of the first electrode 21 and the second electrode 22, ion migration between the first electrode 21 and the third electrode 23 is suppressed. Therefore, with the above configuration, the stretchable device 1G capable of suppressing occurrence of migration may be provided.

### Ninth Embodiment

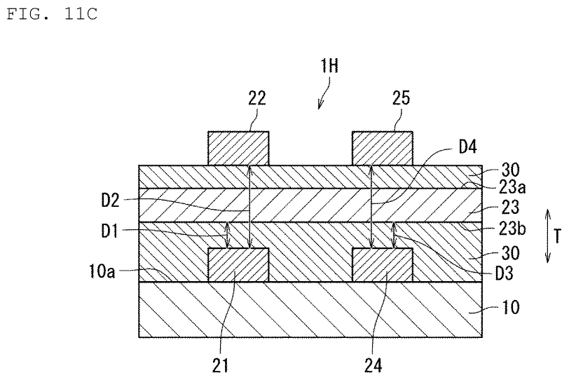

Hereinafter, a stretchable device 1H according to a ninth embodiment will be described with reference to FIGS. 11A to 11C. Each of FIGS. 11A to 11C corresponds to a II-II section of FIG. 1. The stretchable device 1H is different from the stretchable device 1 according to the first embodiment in that a fourth electrode 24 and a fifth electrode 25 are further arranged in addition to the first electrode 21 and the second electrode 22.

For example, the first electrode 21 and the second electrode 24 are located on the same plane. That is, the first electrode 21 and the second electrode 22 are provided on the first main surface 10a of the stretchable substrate 10. The insulating layer 30 is provided on the first main surface 10a of the stretchable substrate 10 so as to cover the first electrode 21 and the second electrode 22. The third electrode 23 is provided so as to face the first electrode 21 and the second electrode 22 with the insulating layer 30 interposed between them on the second surface 23bside. The fourth electrode 24 and the fifth electrode 25 are arranged on the insulating layer located on the first surface 23a side of the third electrode 23. The fourth electrode 24 and the fifth electrode 25 may be located on the same plane. That is, the fourth electrode 24 and the fifth electrode 25 are arranged so as to face the first surface 23a of the third electrode 23 via the insulating layer 30. In the stretchable device 1G having such a configuration, the first electrode 21 and the second electrode 22, and the fourth electrode 24 and the fifth electrode 25 are laminated with the insulating layer 30 and the third electrode 23 interposed between them.

The ionization tendency of a conductive material as a main component of the third electrode 23 is smaller than ionization tendency of a conductive material as a main component of the fourth electrode 24 and ionization tendency of a conductive material as a main component of the fifth electrode 25. For example, both the fourth electrode 24 and the fifth electrode 25 can be silver electrodes, and the third electrode 23 can be a carbon electrode. Ionization tendency of a conductive material as a main component of the third electrode 23, that is, carbon is smaller than ionization tendency of a conductive material as a main component of the fourth electrode 24, that is, silver, and ionization tendency of a conductive material as a main component of the fifth electrode 25, that is, silver.

Further, a shortest distance D3 between the fourth electrode 24 and the third electrode 23 is smaller than a shortest distance D4 between fourth electrode 24 and fifth electrode 25. The shortest distance D3 refers to a minimum value of a distance of a facing direction of the fourth electrode 24 and the third electrode 23 (in this embodiment, the thickness direction T of the stretchable substrate 10). The shortest distance D4 refers to a minimum value of a distance of a facing direction of the fourth electrode 24 and the fifth electrode 25 (in this embodiment, a left-right direction in FIG. 2). The shortest distance D3 and the shortest distance D4 only need to be measured in a section parallel to the thickness direction T of the stretchable substrate 10 and intersecting the fourth electrode 24, the fifth electrode 25, and the third electrode 23. In this embodiment, the shortest distance D3 and the shortest distance D4 may also be measured, for example, in a section passing through the center in an extending direction of the fourth electrode 24 and orthogonal to an extending direction of the fourth electrode 24.

According to the above configuration, since the shortest distance D3 between the fourth electrode 24 and the third electrode 23 is smaller than the shortest distance D4 between the fourth electrode 24 and the fifth electrode 25, intensity of an electric field formed between the fourth electrode 24 and the third electrode 23 is larger than intensity of an electric field formed between the fourth electrode 24 and the fifth electrode 25. For this reason, ion migration between the fourth electrode 24 and the fifth electrode 25 is suppressed, and as a result, migration between the fourth electrode 24 and the fifth electrode 25 can be suppressed. Furthermore, since ionization tendency of a conductive material as a main component of the third electrode 23 is smaller than ionization tendency of a conductive material as a main component of the fourth electrode 24 and ionization tendency of a conductive material as a main component of the fifth electrode 25, migration that may occur between the fourth electrode 24 and the third electrode 23 is also suppressed. By the above, it is possible to suppress migration that may occur in the stretchable device 1.

That is, according to the above configuration, it is possible to laminate and arrange a plurality of electrodes while preventing migration between electrodes by the third electrode 23. With a structure in which a plurality of electrodes are multilayered, an area of the stretchable device can be reduced as compared with a structure in which a plurality of electrodes are arranged on the same plane. For this reason, a more downsized stretchable device can be obtained.

Polarities of potentials of the first to fifth electrodes may be such that the first electrode 21 and the fourth electrode 24 have the same potential polarity, while the second electrode 22, the third electrode 23, and the fifth electrode 25 have the same potential polarity different from the above potential polarity. For example, polarities of potentials of the first electrode 21 and the fourth electrode 24 may be negative, and polarities of potentials of the second electrode 22, the third electrode 23, and the fifth electrode 25 may be positive. According to the above configuration, movement of a metal ion from the second electrode 22 and the fifth electrode 25 having positive polarity is suppressed by the presence of the third electrode 23. For this reason, occurrence of migration can be suitably suppressed also in a laminated stretchable device including a plurality of electrodes.

Arrangement of the first electrode 21, the second electrode 22, the fourth electrode 24, and the fifth electrode 25 illustrated in FIG. 8 is exchangeable with each other. In short, the first electrode 21, the second electrode 22, the fourth electrode 24, and the fifth electrode 25 are interchangeable in terms of arrangement. For example, as illustrated in FIG. 11B, arrangement of the fourth electrode 24 and arrangement of the fifth electrode 25 may be reversed as compared with the stretchable device 1H in FIG. 11A. That is, electrodes having the same polarity of potential may be arranged so as to face each other with the third electrode 23 interposed between them, and alternatively, electrodes having different polarities of potential may be arranged so as to face each other with the third electrode 23 interposed between them.

Alternatively, as illustrated in FIG. 11C, arrangement of the second electrode 22 and arrangement of the fourth electrode 24 may be reversed as compared with the stretchable device 1H in FIG. 11A. Specifically, the first electrode 21 and the fourth electrode 24 having the same polarity of potential may be located on the same plane, and the second electrode 22 and the fifth electrode 25 having the same polarity of potential may be located on the same plane on the opposite side across the third electrode 23. In other words, a plurality of electrodes having the same polarity of potential may be arranged on the same plane, and electrodes having different polarities of potential may be arranged to face each other with the third electrode 23 interposed between them. According to such a configuration, a movement path of an ion between the first electrode 21 and the second electrode 22, and the fourth electrode 24 and the fifth electrode 25 is physically blocked by the third electrode 23. By the above, the presence of the third electrode 23 prevents ion migration across the third electrode 23, so that occurrence of migration can be more suitably suppressed.

Note that each of the embodiments is exemplification, and the present disclosure is not limited to each of the embodiments. Further, each drawing illustrates exemplification of a constituent element, and does not limit a shape. Further, partial replacement or combination of configurations shown in different embodiments is possible.

<1> A stretchable device including: a stretchable substrate; and a first electrode, a second electrode, and a third electrode on the stretchable substrate, in which a first ionization tendency of a conductive material as a main component of the third electrode is smaller than a second ionization tendency of a conductive material as a main component of the first electrode and a third ionization tendency of a conductive material as a main component of the second electrode, and a shortest distance between the first electrode and the third electrode is smaller than a shortest distance between the first electrode and the second electrode.

<2> The stretchable device according to <1>, in which a first polarity of potential of the first electrode is different from a second polarity of potential of the second electrode, and a third polarity of potential of the third electrode is different from the first polarity of the potential of the first electrode.

<3> The stretchable device according to <2>, in which the first polarity of the potential of the first electrode is negative.

<4> The stretchable device according to any one of <1> to <3>, in which the stretchable substrate has a first main surface, the first electrode, the second electrode, and the third electrode are on the first main surface, the first electrode and the second electrode are arranged on the same plane, and the third electrode is arranged at a position different from the first electrode and the second electrode in a thickness direction of the stretchable substrate, the stretchable device further including an insulating layer at least between the first electrode and the third electrode and between the second electrode and the third electrode.

<5> The stretchable device according to <4>, in which the third electrode, the insulating layer, the first electrode, and the second electrode are laminated in this order from the first main surface side.

<6> The stretchable device according to <4> or <5>, in which the insulating layer includes a first portion between the first electrode and the third electrode, and a second portion between the second electrode and the third electrode, and the first portion and the second portion are separated from each other.

<7> The stretchable device according to any one of <4> to <6>, in which the first electrode and the second electrode, the insulating layer, and the third electrode are laminated in this order from the first main surface side.

<8> The stretchable device according to any one of <1> to <3>, in which the stretchable substrate has a first main surface and a second main surface facing each other, the first electrode and the second electrode are on the first main surface, and the third electrode is on the second main surface.

<9> The stretchable device according to any one of <1> to <8>, in which the third electrode overlaps an entirety of the first electrode when viewed from a thickness direction of the stretchable substrate.

<10> The stretchable device according to <9>, in which the third electrode overlaps an entirety of the first electrode and an entirety of the second electrode when viewed from the thickness direction of the stretchable substrate.

<11> The stretchable device according to any one of <1> to <8>, in which the third electrode does not overlap the first electrode or the second electrode when viewed from a thickness direction of the stretchable substrate.

<12> The stretchable device according to any one of <1> to <11>, in which in a section parallel to a thickness direction of the stretchable substrate and intersecting the first electrode and the third electrode, a sectional area of the third electrode is 105% or less of a sectional area of the first electrode.

<13> The stretchable device according to any one of <1> to <3>, in which the first electrode and the second electrode are arranged such that the third electrode is interposed therebetween, the stretchable device further including an insulating layer between the first electrode and the third electrode and between the second electrode and the third electrode.

<14> The stretchable device according to any one of <1> to <3>, further including a fourth electrode and a fifth electrode on the stretchable substrate, in which the first ionization tendency of the conductive material as the main component of the third electrode is smaller than a fourth ionization tendency of a conductive material as a main component of the fourth electrode and a fifth ionization tendency of a conductive material as a main component of the fifth electrode, and a shortest distance between the fourth electrode and the third electrode is smaller than a shortest distance between the fourth electrode and the fifth electrode.

<15> The stretchable device according to <14>, in which a first polarity of potential of the first electrode is the same as a fourth polarity of potential of the fourth electrode, and a second polarity of potential of the second electrode, a third polarity of potential of the third electrode, and a fifth polarity of potential of the fifth electrode are different from the first polarity of potential of the first electrode and the fourth polarity of potential of the fourth electrode.

<16> The stretchable device according to <14> or <15>, in which the first electrode and the second electrode are arranged on the same plane, the fourth electrode and the fifth electrode are arranged on the same plane, and the stretchable substrate, the first electrode and the second electrode, the third electrode, and the fourth electrode and the fifth electrode are laminated in this order in a thickness direction of the stretchable device, the stretchable device further including an insulating layer between the first electrode, the second electrode, and the third electrode, and between the fourth electrode, the fifth electrode, and the third electrode.

<17> The stretchable device according to <14> or <15>, in which the first electrode and the fourth electrode are arranged on the same plane, the second electrode and the fifth electrode are arranged on the same plane, and the stretchable substrate, the first electrode and the fourth electrode, the third electrode, and the second electrode and the fifth electrode are laminated in this order in a thickness direction of the stretchable device, the stretchable device further including an insulating layer between the first electrode, the fourth electrode, and the third electrode, and between the second electrode, the fifth electrode, and the third electrode.

### DESCRIPTION OF REFERENCE SYMBOLS

1, 1A, 1B, 1C, 1D, 1E, 1F: Stretchable device
10: Stretchable substrate
10a: First main surface
10b: Second main surface
21: First electrode
22: Second electrode
23, 23B, 23C: Third electrode
231: First portion
232: Second portion
30, 30A: Insulating layer
40: Protective layer
A1, A2, A3: Sectional area
D1, D2: Shortest distance
T: Thickness direction of stretchable substrate

1. A stretchable device comprising:
a stretchable substrate; and
a first electrode, a second electrode, and a third electrode on the stretchable substrate, wherein
a first ionization tendency of a conductive material as a main component of the third electrode is smaller than a second ionization tendency of a conductive material as a main component of the first electrode and a third ionization tendency of a conductive material as a main component of the second electrode, and
a shortest distance between the first electrode and the third electrode is smaller than a shortest distance between the first electrode and the second electrode.

2. The stretchable device according to claim 1, wherein
a first polarity of potential of the first electrode is different from a second polarity of potential of the second electrode, and
a third polarity of potential of the third electrode is different from the first polarity of the potential of the first electrode.

3. The stretchable device according to claim 2, wherein the first polarity of the potential of the first electrode is negative.

4. The stretchable device according to claim 1, wherein
the stretchable substrate has a first main surface,
the first electrode, the second electrode, and the third electrode are on the first main surface,
the first electrode and the second electrode are arranged on a same plane, and
the third electrode is arranged at a position different from the first electrode and the second electrode in a thickness direction of the stretchable substrate.

5. The stretchable device according to claim 4, further comprising an insulating layer at least between the first electrode and the third electrode and between the second electrode and the third electrode.

6. The stretchable device according to claim 5, wherein the third electrode, the insulating layer, the first electrode, and the second electrode are laminated in this order from the first main surface side.

7. The stretchable device according to claim 5, wherein
the insulating layer includes a first portion between the first electrode and the third electrode, and a second portion between the second electrode and the third electrode, and
the first portion and the second portion are separated from each other.

8. The stretchable device according to claim 5, wherein the first electrode and the second electrode, the insulating layer, and the third electrode are laminated in this order from the first main surface side.

9. The stretchable device according to claim 1, wherein
the stretchable substrate has a first main surface and a second main surface facing each other,
the first electrode and the second electrode are on the first main surface, and
the third electrode is on the second main surface.

10. The stretchable device according to claim 1, wherein the third electrode overlaps an entirety of the first electrode when viewed from a thickness direction of the stretchable substrate.

11. The stretchable device according to claim 1, wherein the third electrode overlaps an entirety of the first electrode and an entirety of the second electrode when viewed from the thickness direction of the stretchable substrate.

12. The stretchable device according to claim 1, wherein the third electrode does not overlap the first electrode or the second electrode when viewed from a thickness direction of the stretchable substrate.

13. The stretchable device according to claim 1, wherein in a section parallel to a thickness direction of the stretchable substrate and intersecting the first electrode and the third electrode, a sectional area of the third electrode is 105% or less of a sectional area of the first electrode.

14. The stretchable device according to claim 1, wherein the first electrode and the second electrode are arranged such that the third electrode is interposed therebetween.

15. The stretchable device according to claim 14, further comprising an insulating layer between the first electrode and the third electrode and between the second electrode and the third electrode.

16. The stretchable device according to claim 1, further comprising a fourth electrode and a fifth electrode on the stretchable substrate, wherein
the first ionization tendency of the conductive material as the main component of the third electrode is smaller than a fourth ionization tendency of a conductive material as a main component of the fourth electrode and a fifth ionization tendency of a conductive material as a main component of the fifth electrode, and
a shortest distance between the fourth electrode and the third electrode is smaller than a shortest distance between the fourth electrode and the fifth electrode.

17. The stretchable device according to claim 16, wherein
a first polarity of potential of the first electrode is same as a fourth polarity of potential of the fourth electrode, and
a second polarity of potential of the second electrode, a third polarity of potential of the third electrode, and a fifth polarity of potential of the fifth electrode are different from the first polarity of potential of the first electrode and the fourth polarity of potential of the fourth electrode.

18. The stretchable device according to claim 16, wherein
the first electrode and the second electrode are arranged on a same plane,
the fourth electrode and the fifth electrode are arranged on a same plane, and
the stretchable substrate, the first electrode and the second electrode, the third electrode, and the fourth electrode and the fifth electrode are laminated in this order in a thickness direction of the stretchable device.

19. The stretchable device according to claim 18, further comprising an insulating layer between the first electrode, the second electrode, and the third electrode, and between the fourth electrode, the fifth electrode, and the third electrode.

20. The stretchable device according to claim 16, wherein
the first electrode and the fourth electrode are arranged on a same plane,
the second electrode and the fifth electrode are arranged on a same plane, and
the stretchable substrate, the first electrode and the fourth electrode, the third electrode, and the second electrode and the fifth electrode are laminated in this order in a thickness direction of the stretchable device,
the stretchable device further comprising an insulating layer between the first electrode, the fourth electrode, and the third electrode, and between the second electrode, the fifth electrode, and the third electrode.
